(19) United States
(12) Patent Application Publication
(10) Pub. No.: US 2018/0366606 A1
(43) Pub. Date: Dec. 20, 2018

(54) SOLAR CELL MODULE

(71) Applicant: Panasonic Intellectual Property Management Co., Ltd., Osaka (JP)

(72) Inventors: Youhei MURAKAMI, Osaka (JP); Akimichi MAEKAWA, Osaka (JP); Haruhisa HASHIMOTO, Osaka (JP); Hiroshi KANNO, Osaka (JP); Masahito YAMANA, Hyogo (JP)

(21) Appl. No.: 16/108,705

(22) Filed: Aug. 22, 2018

Related U.S. Application Data
(63) Continuation of application No. PCT/JP2017/006471, filed on Feb. 22, 2017.

(30) Foreign Application Priority Data
Feb. 25, 2016 (JP) 2016-034899

(51) Int. Cl. H01L 31/054; H01L 31/049; H01L 31/0224

(52) U.S. Cl. CPC H01L 31/0547; H01L 31/022475; H01L 31/022425; H01L 31/049

(57) ABSTRACT

A solar cell module includes: a solar cell; a light reflector above a surface of the solar cell or around the solar cell, the light reflector being elongated and including a light reflective film and an insulating component; a protective component that covers the surface of the solar cell; and an encapsulant between (i) the solar cell and the light reflector and (ii) the protective component. The light reflective film has an uneven structure in which a recessed portion and a protruding portion are repeated in a direction crossing a longitudinal direction of the light reflector, and a tangential direction of at least part of a ridge line of the protruding portion and the longitudinal direction intersect when the solar cell is seen in a plan view.

### CROSS REFERENCE TO RELATED APPLICATIONS

This application is a U.S. continuation application of PCT International Patent Application Number PCT/JP2017/006471 filed on Feb. 22, 2017, claiming the benefit of priority of Japanese Patent Application Number 2016.034899 filed on Feb. 25, 2016, the entire contents of which are hereby incorporated by reference.

### BACKGROUND

1. Technical Field

The present disclosure relates to a solar cell module.

2. Description of the Related Art

Conventionally, solar cell modules have been developed as photoelectric conversion devices that convert light energy into electric energy. Solar cell modules can directly convert inexhaustible sunlight into electricity, and thus generate power with less environmental impact and more cleanly than power generation using fossil fuels. As a result, the solar cell modules are expected to provide new energy resources.

For example, a solar cell module has a structure in which solar cells are sealed with an encapsulant, between a front surface protective component and a back surface protective component. In the solar cell module, the solar cells are arranged in a matrix.

Conventionally, a solar cell module has been proposed in which in order to effectively use sunlight emitted on a space between solar cells, a light reflector projecting out from the light-receiving surfaces of the solar cells and inclined relative to the light-receiving surfaces is provided in the space between the solar cells (for example, Patent Literature (PTL 1) (Japanese Unexamined Patent Application Publication No. 2013-98496)).

### SUMMARY

In the solar cell module of PTL 1, the light reflector between the solar cells has a symmetric prism shape so as to evenly redistribute, to the solar cells on both sides, light entered between the solar cells. In this case, although it is expected to increase output because of the light confinement effect of confining light to the solar cell module, there are cases where most of reflected light from the light reflector is emitted outside of the solar cell module depending on the incident angle of incident light. For this reason, there is concern that the emitted reflected light illuminates part of the module surface, which impairs the appearance of the solar cell module and further causes visual discomfort to a person.

The present disclosure has an object to provide a solar cell module that reduces illumination on part of the module surface provided by emitted reflected light.

In order to achieve the above object, a solar cell module according to one aspect of the present disclosure includes: a solar cell; a light reflector above a surface of the solar cell or around the solar cell, the light; reflector being elongated and including a light reflective film and an insulating component; a protective component that covers the surface of the solar cell; and an encapsulant between (i) the solar cell and the light reflector and (ii) the protective component. The light reflective film has an uneven structure in which a recessed portion and a protruding portion are repeated in a direction crossing a longitudinal direction of the light reflector, and a tangential direction of at least part of a ridge line of the protruding portion and the longitudinal direction intersect when the solar cell is seen in a plan view.

A solar cell module according to the present disclosure is capable of reducing illumination on part of the module surface provided by emitted reflected light.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is a plan view of a solar cell module according to Embodiment 1;

FIG. 2 is a cross-sectional view of the solar cell module taken along line II-II of FIG. 1;

FIG. 3 is an enlarged plan view when the solar cell module according to Embodiment 1 is seen from a side facing a front surface;

FIG. 4A is a cross-sectional view (an enlarged cross-sectional view around a light reflector) of the solar cell module taken along line IV-IV of FIG. 3;

FIG. 4B is a cross-sectional view (an enlarged cross-sectional view around a light reflector) of a solar cell module according to Variation 1 of Embodiment 1;

FIG. 4C is a cross-sectional view (an enlarged cross-sectional view around a light reflector) of a solar cell module according to Variation 2 of Embodiment 1;

FIG. 5 is a transparent bottom view (an enlarged transparent bottom view around a light reflector) of the solar cell module according to Embodiment 1;

FIG. 6 is a cross-sectional view indicating a state in which reflected light is emitted when a conventional solar cell module is installed;

FIG. 7A is a transparent plan view (an enlarged transparent plan view around a light reflector) indicating a relationship between a distance between solar cells and a horizontal range of reflected light in the conventional solar cell module;

FIG. 7B is a transparent plan view (an enlarged transparent plan view around a light reflector) indicating a relationship between a distance between solar cells and a horizontal range of reflected light in the solar cell module according to Embodiment 1;

FIG. 8 is a schematic cross-sectional view for illustrating a horizontal range of reflected light in a solar cell module;

FIG. 9 is a perspective view of an installation. model of a solar cell module for analyzing a relationship between a ridge angle of a light reflector and incidence efficiency;

FIG. 10A is a graph illustrating a relationship between a ridge angle of a light reflector and a probability for incident light to reach a solar cell;

FIG. 10B is a graph illustrating a relationship between a ridge angle of a light reflector and reflectance;

FIG. 11 is a transparent plan view (an enlarged transparent plan view around a light, reflector) of a solar cell module according to Embodiment 2; and

FIG. 12 is a transparent plan view (an enlarged transparent plan view around a light reflector) of a solar cell module according to Embodiment 3.

### DETAILED DESCRIPTION OF THE EMBODIMENTS

Hereinafter, solar cell modules according to embodiments of the present disclosure will be described with reference to the drawings. The embodiments described below each show a specific example of the present disclosure. The numerical values, shapes, materials, structural components, the arrangement and connection of the structural components, etc. shown in the following embodiments are mere examples, and are not intended to limit the scope of the present disclosure. Furthermore, among the structural components in the following embodiments, structural components not recited in any one of the independent claims which indicate the broadest concepts of the present disclosure are described as optional structural components.

The figures are schematic diagrams and are not necessarily precise illustrations. Furthermore, in the figures, identical structural components are assigned identical reference signs.

In this specification, a “front surface” of a solar cell denotes a surface through which more light can enter the solar cell in comparison to a “back surface” that is a surface opposite the front surface (more than 50% to 100% of light enters the solar cell through the front surface). Examples of the front surface include a surface through which no light enters from a side facing the “back surface.” In addition, a “front surface” of a solar cell module denotes a surface through which light on a side facing the “front surface” of the solar cell can enter, and a “back surface” of the solar cell module denotes a surface opposite the front surface of the solar cell module. It should be noted that, unless specifically limited, an expression such as “provide a second component on a first component” is not intended only for a case in which the first and second components are provided in direct contact with each other. In other words, examples of this expression include a case in which another component is between the first and second components. It should also be noted that regarding the expression “substantially XX,” for example, “substantially the same” is intended to include not only exactly the same but also something that can be substantially recognized as the same.

### Embodiment 1

### [1. Configuration of Solar Cell Module]

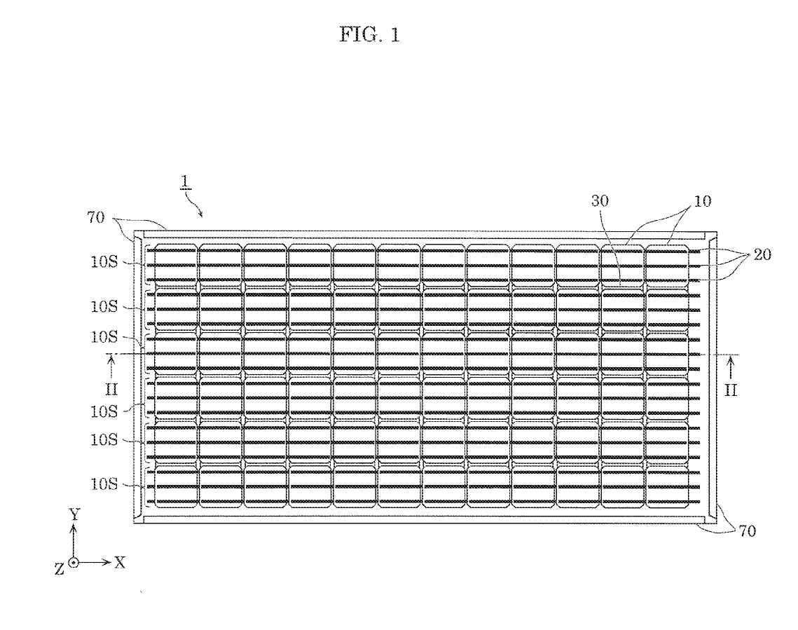

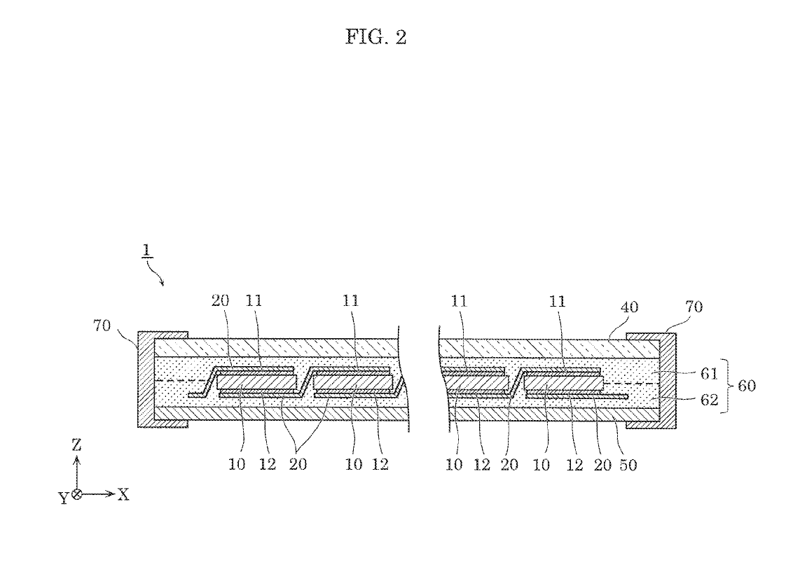

First, the following describes a schematic configuration of solar cell module 1 according to Embodiment 1, with reference to FIG. 1 and FIG. 2.

FIG. 1 is a plan view of solar cell module 1 according to Embodiment 1. FIG. 2 is a cross-sectional view of solar cell module 1 taken along line II-II of FIG. 1.

It should be noted that in FIG. 1 and FIG. 2, the Z axis is perpendicular to a principal surface of solar cell module 1, and the X axis and the Y axis are orthogonal and are both orthogonal to the Z axis. The same applies to the Z axis, the X axis, and the Y axis in the figures described below.

As shown in FIG. 1 and FIG. 2, solar cell module 1 includes solar cells 10, first interconnectors 20, light reflectors 30, front surface protective component 40, back surface protective component 50, encapsulant 60, and frame 70. Solar cell module 1 has a structure in which solar cells 10 are sealed with encapsulant 60, between front surface protective component 40 and back surface protective component 50.

As shown in FIG. 1, solar cell module 1 has, for example, a substantially rectangular shape in a plan view. As an example, solar cell module 1 has a substantially rectangular shape having a width of approximately 1600 mm and a length of approximately 800 mm. It should be noted that solar cell module 1 is not limited to a rectangular shape.

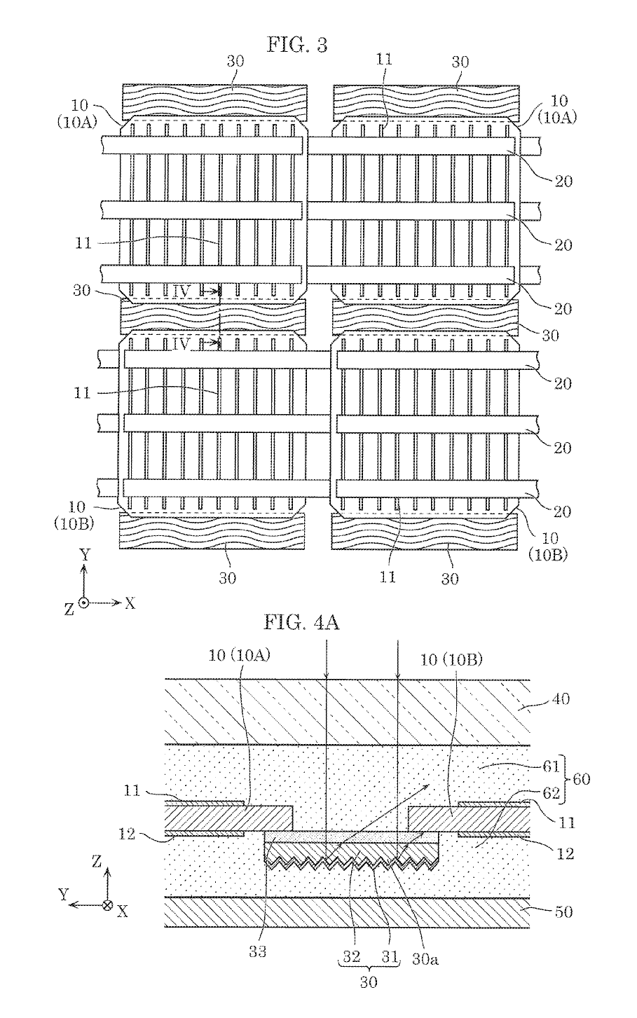

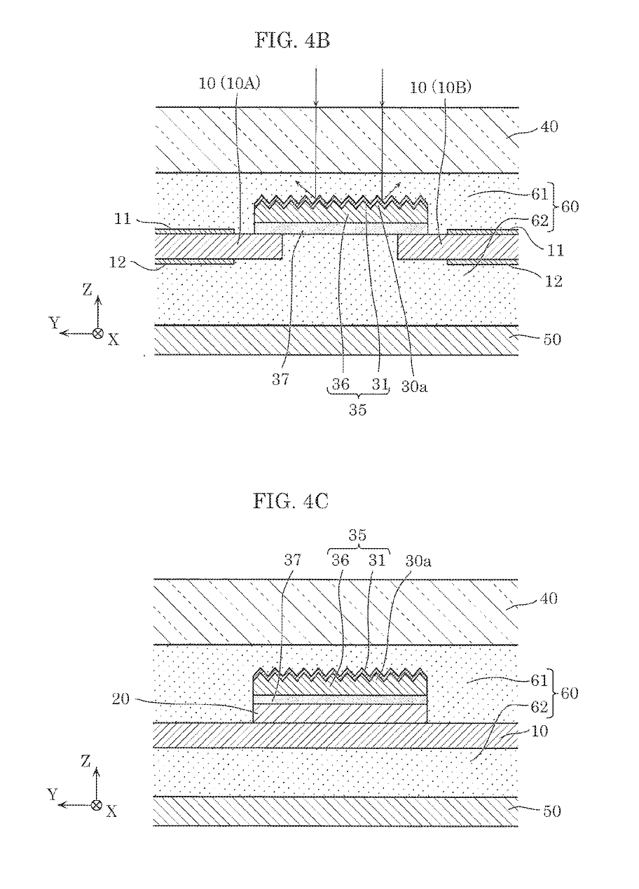

Hereinafter, each of the structural components of solar cell module 1 will be described in further detail, with reference to FIG. 1 and FIG. 2, and also FIG. 3 and FIG. 4.

FIG. 3 is an enlarged plan view when solar cell module 1 according to Embodiment 1 is seen from the side facing the front surface. In other words, FIG. 3 illustrates a state when the solar cell module is seen through from a side facing a principal light-receiving surface (a side facing front surface protective component 40). FIG. 4A is a cross-sectional view of solar cell module 1 according to Embodiment 1, taken along line IV-IV of FIG. 3. It should be noted that FIG. 4A is an enlarged cross-sectional view around light reflector 30.

### [1-1. Solar Cell (Solar Cell Element)]

Solar cell 10 is a photoelectric conversion element (photovoltaic element) that converts light such as sunlight into electrical power. As shown in FIG. 1, solar cells 10 are arranged in rows and columns (a matrix) in the same plane.

Pairs of adjacent solar cells 10 among solar cells 10 linearly aligned are connected by first interconnector 20 to form a string (cell string). Solar cells 10 in one string 105 are electrically connected in series by first interconnector 20.

In Embodiment 1, as shown in FIG. 1, twelve solar cells 10 arranged at equal intervals along the row direction (the X axis direction) are connected by first interconnector 20 to form one string 10S. Strings 10S are farmed. Strings 10S are arranged along the column direction (the Y axis direction). In Embodiment 1, as shown in FIG. 1, six strings 105 are arranged at equal. intervals along the column direction, to be parallel.

It should be noted that each of strings 10S is connected to a second interconnector (not shown) via first interconnector 20. As a result, strings 10S are connected in series or parallel to form a cell array. In Embodiment 1, two adjacent strings 10S are connected in series to form one series connection (a series connection of twenty four solar cells 10), and three such series connections are connected in series to form a series connection of seventy two solar cells 10.

As shown in FIG. 1 and FIG. 3, solar cells 10 are spaced apart from solar cells 10 adjacent in the row direction and the column direction. As described below, light reflectors 30 are disposed in the spaces.

In Embodiment 1, solar cell 10 has a substantially rectangular shape in a plan view. Specifically, solar cell 10 is a 125-mm square having chamfered corners. Thus, one string 10S has a configuration in which sides of two adjacent solar cells 10 face each other. It should be noted that solar cell 10 is not limited to a substantially rectangular shape.

Solar cell 10 has a semiconductor p-n junction as a basic structure. As an example, solar cell 10 includes: an n-type single-crystal silicon substrate, which is an n-type semiconductor substrate; an n-type amorphous silicon layer and an n-side electrode that are disposed in listed order on a side facing one principal surface of the n-type single-crystal silicon substrate; and a p-type amorphous silicon layer and a p-side electrode that are disposed in listed order on a side facing the other principal surface of the n-type single-crystal silicon substrate. It should be noted that a passivation layer such as an i-type amorphous silicon layer, a silicon oxide layer, and a silicon nitride layer may be disposed between the n-type single-crystal silicon substrate and the n-type amorphous silicon layer. In addition, a passivation layer may also be disposed between the n-type single-crystal silicon substrate and the p-type amorphous silicon layer. The n-side electrode and the p-side electrode are transparent electrodes such as indium tin oxide (ITO) electrodes.

It should be noted that although, in Embodiment 1, solar cell 10 is disposed so that the n-side electrode is on the side facing the principal light-receiving surface of solar cell module 1 (the side facing front surface protective component 40), the present disclosure is not limited to this. Moreover, when solar cell module 1 is a monofacial module, an electrode on a side facing the back surface (the p-side electrode in Embodiment 1) need not be transparent, and may be, for example, a metal electrode having reflectivity.

In each solar cell 10, a front surface is a surface facing front surface protective component 40, and a back surface is a surface facing back surface protective component 50. As shown in FIG. 2 and FIG. 4A, front surface collector electrode 11 and back surface collector electrode 12 are formed on solar cell 10. Front surface collector electrode 11 is electrically connected to an electrode (e.g., the n-type electrode) on a side facing the front surface of solar cell 10. Back surface collector electrode 12 is electrically connected to an electrode (e.g., the p-type electrode) on a side facing the back surface of solar cell 10.

Each of front surface collector electrode 11 and back surface collector electrode 12 includes, for example, finger electrodes formed linearly to be orthogonal to a direction in which first interconnector 20 extends, and bus bar electrodes connected to the finger electrodes and formed linearly along a direction crossing the finger electrodes (the direction in which first interconnector 20 extends). The number of the bus bar electrodes is equal to, for example, the number of first interconnectors 20, and is three in Embodiment 1. It should be noted that front surface collector electrode 11 and back surface collector electrode 12 have the same shape, but the present disclosure is not limited to this.

Front surface collector electrode 11 and back surface collector electrode 12 are made of a conductive material having low resistance, such as silver (Ag). For example, front surface collector electrode 11 and back surface collector electrode 12 can be formed by screen printing a conductive paste (e.g., silver paste) obtained by dispersing a conductive filler such as silver in a binder resin, in a predetermined pattern.

In solar cell 10 having such a configuration, both the front surface and the back surface serve as light-receiving surfaces. When light enters solar cell 10, charge carriers are generated in a photoelectric converter of solar cell 10. The generated charge carriers are collected by front surface collector electrode 11 and back surface collector electrode 12, and flow into first interconnector 20. The charge carriers generated in solar cell 10 can be efficiently taken out to an external circuit by disposing front surface collector electrode 11 and back surface collector electrode 12 as described above.

### [1-2. First Interconnector (Interconnector)]

As shown in FIG. 1 and FIG. 2, first interconnectors 20 (interconnectors) electrically connect pairs of adjacent solar cells 10 in string 10S. In Embodiment 1, as shown in FIG. 1 and FIG. 3, each pair of adjacent solar cells 10 is connected by three first interconnectors 20 that are substantially parallel to each other. Each first interconnector 20 extends along the alignment of the pair of adjacent solar cells 10 to be connected. As shown in FIG. 2, regarding each first interconnector 20, one end portion of first interconnector 20 is disposed on the front surface of one of the pair of adjacent solar cells 10, and the other end portion of first interconnector 20 is disposed on the back surface of the other of the pair of adjacent solar cells 10. In the pair of adjacent solar cells 10, each first interconnector 20 electrically connects front surface collector electrode 11 of one of the pair of solar cells 10 and back surface collector electrode 12 of the other of the pair of solar cells 10. For example, first interconnectors 20 and bus bar electrodes of front surface collector electrode 11 and back surface collector electrode 12 on solar cell 10 are bonded together with a conductive adhesive such as a solder material, or a resin adhesive. When first interconnectors 20 and the bus bar electrodes of front surface collector electrode 11 and back surface collector electrode 12 on solar cell 10 are bonded together with a resin adhesive, the resin adhesive may contain conductive particles.

First interconnectors 20 are elongated conductive lines, and are ribbon-shaped metal foil, for example. First interconnectors 20 can be produced by, for example, cutting metal foil such as copper foil or silver foil having surfaces entirely covered with solder, silver, etc. into strips having a predetermined length.

### [1-3. Configuration of Light Reflector]

As shown in FIG. 4A, light reflector 30 is disposed on the side facing the back surface of solar cell 10. Light reflector 30 includes light reflective film 31 and insulating component 32.

Light reflective film 31 is disposed extending from an end portion of solar cell 10 toward adjacent solar cell 10. More specifically, on a side facing back surfaces of solar cell 10A and solar cell 10B that are adjacent to and spaced apart from each other, light reflective film 31 is disposed extending across the space between solar cells 10A and 10B.

Insulating component 32 is disposed between the back surface of solar cell 10 and light reflective film 31. Insulating component 32 is closer to the principal light-receiving surface of solar cell module 1 than light reflective film 31. Thus, insulating component 32 is made of a light-transmissive material such as a transparent material, in order that a surface of light reflective film 31 on the side facing the principal light-receiving surface reflects light that has entered through the principal light-receiving surface of solar cell module 1.

Examples of a specific material of insulating component 32 include polyethylene terephthalate (PET) or acryl, and insulating component 32 is a transparent PET sheet in Embodiment 1.

Insulating component 32 includes recesses and protrusions 30a. Regarding recesses and protrusions 30a, for example, a height between a recessed portion (trough) and a protruding portion (peak) is at least 5 μm and at most 100 μm, and a space (intervals) between adjacent protruding portions is at least 20 μm and at most 400 μm. In Embodiment 1, a height between the recessed portion and the protruding portion is 12 μm, and a space (intervals) between adjacent protruding portions is 40 μm.

In Embodiment 1, light reflector 30 is bonded to solar cell 10 via adhesive component 33 on insulating component 32 on a side facing solar cell 10. Adhesive component 33 is disposed between insulating component 32 and solar cell 10, and bonds insulating component 32 and solar cell 10 together. It should be noted that adhesive component 33 is disposed on an entire surface of insulating component 32. Adhesive component 33 is, for example, a heat-sensitive adhesive or pressure-sensitive adhesive including ethylene-vinyl acetate (EVA), and is a light-transmissive material. Accordingly, light reflector 30 can be bonded and fixed to solar cell 10 by thermo compression bonding. It should be noted that although insulating component 32 and light reflective film 31 are included in light reflector 30 in Embodiment 1, insulating component 32, light reflective film 31, and adhesive component 33 may be included in light reflector 30. In other words, light reflector 30 has a three-layered structure of light reflective film 31, insulating component 32, and adhesive component 33.

Light having entered a gap region between solar cells 10 is reflected by a front surface of light reflector 30. This reflected light is reflected again by an interface between front surface protective component 40 and an outer space of solar cell module 1, and is emitted on solar cell 10. As a result, it is possible to increase the photoelectric conversion efficiency of solar cell module 1 as a whole.

It should be noted that a light reflector according to the present disclosure is not limited to a configuration in which light reflector 30 according to Embodiment 1 is disposed on the back surface of solar cell 10.

FIG. 4B is a cross-sectional view enlarged cross-sectional view around a light reflector) of a solar cell module according to Variation 1 of Embodiment 1. As shown in FIG. 4B, light reflector 35 is disposed on a side facing a front surface of solar cell 10 according to Variation 1. Light reflector 35 includes light reflective film 31 and insulating component 36.

On a side facing front surfaces of solar cell 10A and solar cell 10B that are adjacent to and spaced apart from each other, light reflective film 31 is disposed extending across the space between solar cells 10A and 10B.

Insulating component 36 is disposed between the front surface of solar cell 10 and light reflective film 31. Insulating component 36 is closer to solar cell 10 than light reflective film 31. Insulating component 36 is made of the same specific material as insulating component 32, but the specific material need not be transparent.

Insulating component 36 has an uneven structure similar to recesses and protrusions 30a of insulating component 32.

Adhesive component 37 is disposed between insulating component 36 and solar cell 10, and bonds insulating component 36 and solar cell 10 together. It should be noted that adhesive component 37 is disposed on an entire surface of insulating component 36. Adhesive component 37 is made of the same material as insulating component 36.

Light having entered a gap region between solar cells 10 is reflected by a front surface of light reflector 35 according to Variation 1. This reflected light is reflected again by an interface between front surface protective component 40 and an outer space of solar cell module 1, and is emitted on solar cell 10. As a result, it is possible to increase the photoelectric conversion efficiency of solar cell module 1 as a whole.

It should be noted that when light reflector 35 is disposed on the side facing the front surface of solar cell 10, an effective region (a power generation region) of solar cell 10 may be shaded by light reflector 35 in an overlapping portion of solar cell 10 with light reflector 35, which blocks light from entering the effective region. In contrast, Embodiment 1 in which light reflector 30 is disposed on the side facing the back surface of solar cell 10 makes it possible to more considerably reduce such blocked light.

FIG. 4C is a cross-sectional view (an enlarged cross-sectional view around a light reflector) of a solar cell module according to Variation of Embodiment 1. As shown in FIG. 4C, light reflector 35 is disposed on a front surface of solar cell 10 according to Variation 2. The light reflector according to Variation 2 is made of the same material as the light reflector according to Variation 1, but differs from the light reflector according to Variation 1 only in location. Hereinafter, description of points that are the same as those of the light reflector according to Variation 1 will be omitted, and description will he focused on the points of difference.

Light reflector 35 according to Variation 2 is disposed on first interconnector 20 on the front surface of solar cell 10.

With the configuration of light reflector 35 according to Variation 2, light having entered an upper portion of first interconnector 20 on solar cell 10 is reflected by a front surface of light reflector 35. This reflected light is reflected again by an interface between front surface protective component 40 and an outer space of solar cell module 1, and is redistributed onto solar cell 10.

As a result, it is possible to increase the photoelectric conversion efficiency of solar cell module 1 as a whole.

### [1-4. Surface Structure of Light Reflector]

As shown in FIG. 4A, light reflective film 31 is disposed on a surface on which recesses and protrusions 30a of insulating component 32 are disposed. Light reflective film 31 is, for example, a metal film (metal reflective film) including metal such as aluminum or silver. Light reflective film 31, which is a metal film, is formed on the surface of recesses and protrusions 30a of insulating component 32 by vapor deposition etc. Accordingly, the surface shape of light reflective film 31 is caused to conform to the unevenness of recesses and protrusions 30a, and light reflective film 31 has an uneven structure in which recess portions and protruding portions are repeated in a direction crossing a longitudinal direction of light reflector 30.

Here, as shown in FIG. 3, in the uneven structure of light reflective film 31 included in each light reflector 30, the ridge lines of the protruding portions (peaks) are wavy without points of discontinuity when solar cell 10 is seen in a plan view. It should be noted that light reflective film 31. is seen through via adhesive component 33 and insulating component 32 in each light reflector 30 shown in FIG. 3. The surface structure of each light reflector 30 will be described in detail below with reference to FIG. 5.

FIG. 5 is a transparent bottom view (an enlarged transparent bottom view around light reflector 30) of solar cell module 1 according to Embodiment 1. Specifically, FIG. 5 is a bottom view obtained by seeing through light reflector 30 and two solar cells 10 adjacent to light reflector 30 from a side facing back surface protective component 50 (the Z axis negative side). In addition, a cross-sectional view of light reflector 30 taken along a YZ plane is shown below FIG. 5. As shown in FIG. 5, light reflective film 31 has protruding portion (peak) 30t and recessed portion (trough) 30v that are repeated in a latitudinal direction (the Y axis direction) of light reflector 30. Moreover, a ridge line of protruding portion (peak) 30t is a wavy line in a plan view. Here, when solar cell 10 is seen in the plan view, a tangential direction of part of the ridge line of protruding portion (peak) 30t and the longitudinal direction of light reflector 30 intersect. In other words, the maximum angle θ_{X} (deg) that can be formed by the tangential direction of the part of the ridge line of protruding portion (peak) 30t and the longitudinal direction of light reflector 30 is not 0 degrees. To put it differently, the longitudinal direction of light reflector 30 and a pair of parallel sides of solar cells 10A and 10B facing each other across light reflector 30 are parallel, and thus an extension direction of the pair of the sides and the tangential direction of the part of the ridge line of protruding portion (peak) 30t intersect.

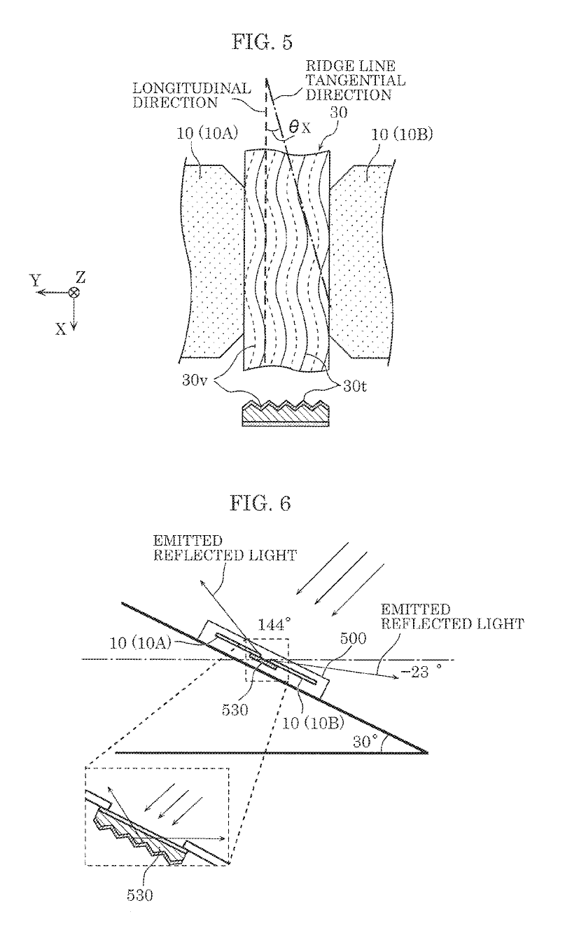

FIG. 6 is a cross-sectional view indicating a state in which reflected light is emitted when conventional solar cell module 500 is installed. Specifically, FIG. 6 is a cross-sectional view indicating a state in which conventional solar cell module 500 is installed on a structure (e.g., the roof of a house) at a horizontal angle of 30 degrees. It should be noted that conventional solar cell module 500 includes light reflector 530 having an uneven structure, in a gap region between adjacent solar cells 10A and 10B. Here, a ridge line of a protruding portion in the uneven structure of light reflector 530 is a straight line parallel to a longitudinal direction of light reflector 530. In this case, although it is expected to increase output because of the light confinement effect of confining light to solar cell module 500, there are cases where most of reflected light from light reflector 530 is emitted outside of solar cell module 500 depending on the incident angle of incident light. For example, at a culmination time on the winter solstice having a large amount of incident light, reflected light is emitted outside of solar cell module 500 at 144 degrees and −23 degrees relative to the horizontal plane. Accordingly, the emitted reflected light illuminates the module surface more strongly than in other seasons or other time periods, which impairs the appearance of solar cell module 500 and further causes visual discomfort to a person.

In contrast, with solar cell module 1 according to Embodiment 1, the characteristic surface structure of light reflector 30 shown in FIG. 5 makes it possible to reduce illumination on part of the module surface. The surface structure of each light reflector 30 according to Embodiment 1 will be described in detail below.

### [1-5. Ridge Line Angle Range of Light Reflector]

First, the following describes the upper limit of the maximum angle θ_{X} (deg) formed by a tangential direction of a ridge line of protruding portion (peak) 30t and the longitudinal direction of light reflector 30.

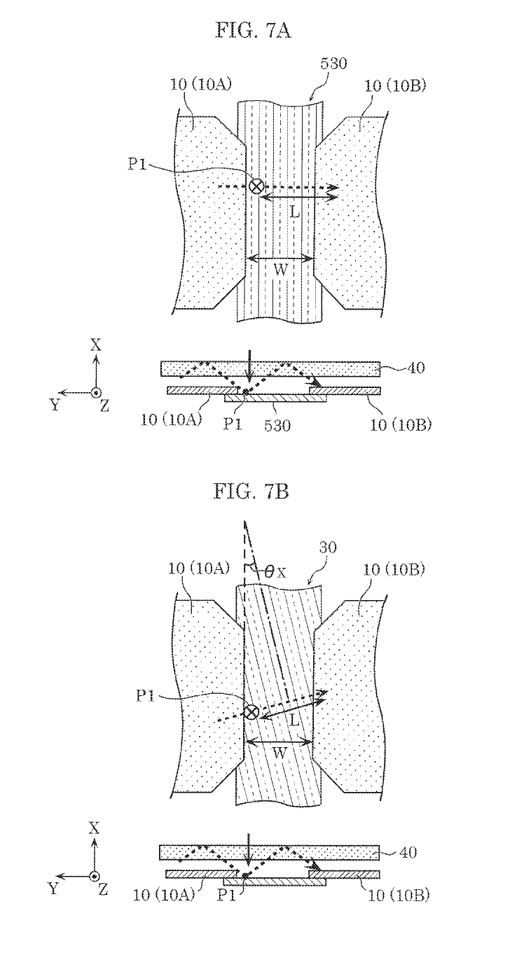

FIG. 7A is a transparent plan view (an enlarged transparent plan view around a light reflector) indicating a relationship between a distance between solar cells and a horizontal range of reflected light in conventional solar cell module 500. FIG. 7B is a transparent plan view (an enlarged transparent plan view around a light reflector) indicating a relationship between a distance between solar cells and a horizontal range of reflected light in solar cell module 1 according to Embodiment 1.

In FIG. 7A, L denotes a horizontal range from first point P1 when, in the case where sunlight enters first point P1 on light reflector 530 perpendicularly, the incident light is reflected again by front surface protective component 40 and reaches a horizontal plane including the front surface of solar cell 10. Further, W denotes a width of part of light reflector 530 which is seen from an incident light side (the Z axis positive side). In the example shown in FIG. 7A, since light reflector 35 is disposed on the side facing the back surface of solar cell 10, width W of part of light reflector 35 which is seen from the incident light side is a distance between edges of adjacent solar cells 10. In this case, a condition that the incident light on light reflector 530 is effectively redistributed to the front surface of solar cell 10 is expressed by L>W. It should be noted that with the arrangement of light reflectors 35 according to Variations 1 and 2, width W of each light reflector 35 seen from the incident light side (the Z axis positive side) is defined as the width of light reflector 35 itself. In contrast, width W of the part of light reflector 30 according to Embodiment 1 is defined as a distance between solar cells 10A and 10B.

In contrast, in FIG. 7B, L denotes a horizontal range from first point P1 when, in the case where sunlight enters first point P1 on light reflector 30 perpendicularly, the incident light is reflected again by front surface protective component 40 and reaches a horizontal plane including the front surface of solar cell 10. Further, W denotes a width of part of light reflector 30 which is seen from an incident light side (the Z axis positive side). In this case, a condition that the incident light on light reflector 30 is effectively redistributed to the front surface of solar cell 10 is expressed by Expression 1 below. Further, by expanding Expression 1, the upper limit angle of the maximum angle θ_{X} is defined by Expression 2.

$$\begin{matrix}[ Math . 1 ] & \\ L cos {θ}_{X} > W & ( Expression 1 ) \\ [ Math . 2 ] & \\ {θ}_{X} < {cos}^{- 1} ( \frac{W}{L} ) & ( Expression 2 )\end{matrix}$$

FIG. 8 is a schematic cross-sectional view for illustrating horizontal range L of reflected light in solar cell module 1. As shown in FIG. 8, horizontal range L is expressed by Expression 3 below, where a vertex angle of a protruding portion of light reflective film 31 is θ_{Z} (deg), and a distance from the interface between front surface protective component 40 and the outer space of solar cell module 1 is d.

[Math. 3]

L=−2d·tan θ_{Z} (Expression 3)

Next, the following describes the lower limit of the maximum angle θ_{X} (deg) formed by the tangential direction of the ridge line of protruding portion (peak) 30t and the longitudinal direction of light reflector 30.

The lower limit of the maximum angle θ_{X} (deg) is calculated by a simulation analysis of a relationship between the maximum angle θ_{X} (deg) and incidence efficiency of light incident on solar cell module 1. Examples of this simulation analysis method include a ray tracing method, and examples of simulation software include illumination design analysis software (LightTools of Synopsys).

FIG. 9 is a perspective view of an installation model of solar cell module 1 for a simulation analysis of a relationship between a ridge angle of light reflector 30 and incidence efficiency. As shown in FIG. 9, solar cell module 1 including two adjacent solar cells 10A and 10B and light reflector 30 disposed in the gap region is installed southwards on a structure (the roof of a house) at a horizontal angle of 30 degrees. Further, solar cell 10A is disposed above solar cell 10B (in the positive direction of the Y axis), and light reflector 30 is disposed between solar cells 10A and 10B in a horizontal direction (the east-west direction and the X axis direction) as a longitudinal direction. In addition, it is assumed that a shape of a ridge line of a protruding portion of light reflector 30 is not a wavy shape but a linear shape having certain angle θ_{X} formed with the longitudinal direction of light reflector 30 (a surface shape of light reflector 30A to be described in Embodiment 2), and vertex angle θ_{Z} of the protruding portion is 120 degrees. It should be noted that an analysis range is an area of 240 mm×120 mm as shown in FIG. 9, and the location of a sunlight source is set according to the longitude (e.g., 136 degrees east longitude) and latitude (e.g., 35 degrees north latitude) of a location in which solar cell module 1 is installed. In the above installation mode of solar cell module 1, a probability of incident light reaching a cell surface and reflectance of incident light reflected to the outside of solar cell module 1 when angle θ_{X} of light reflector 30 is varied in a range from 0 degrees to 30 degrees are calculated for a culmination time of each of the vernal equinox, the summer solstice, and the winter solstice, using the above simulation software.

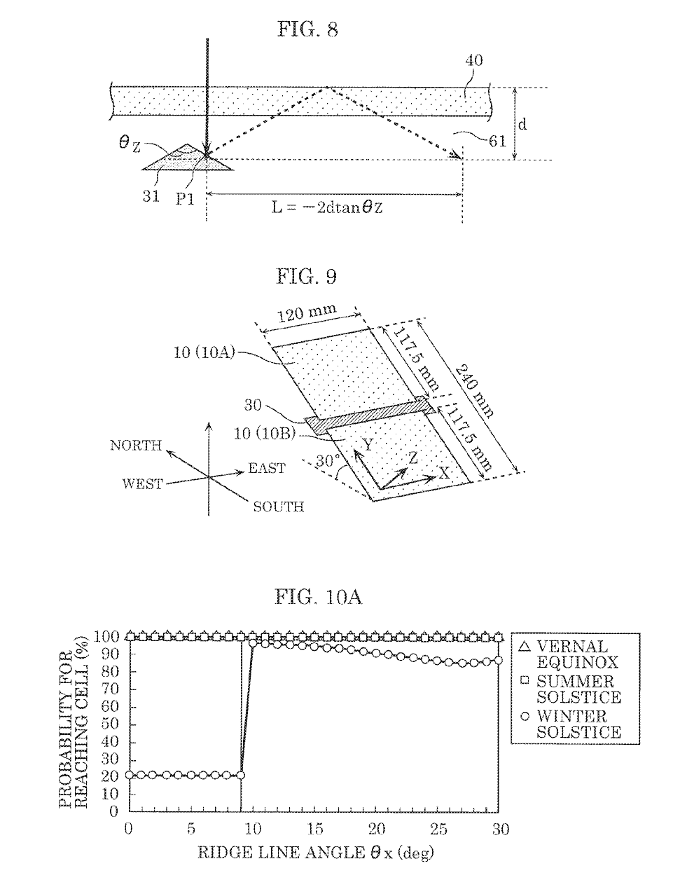

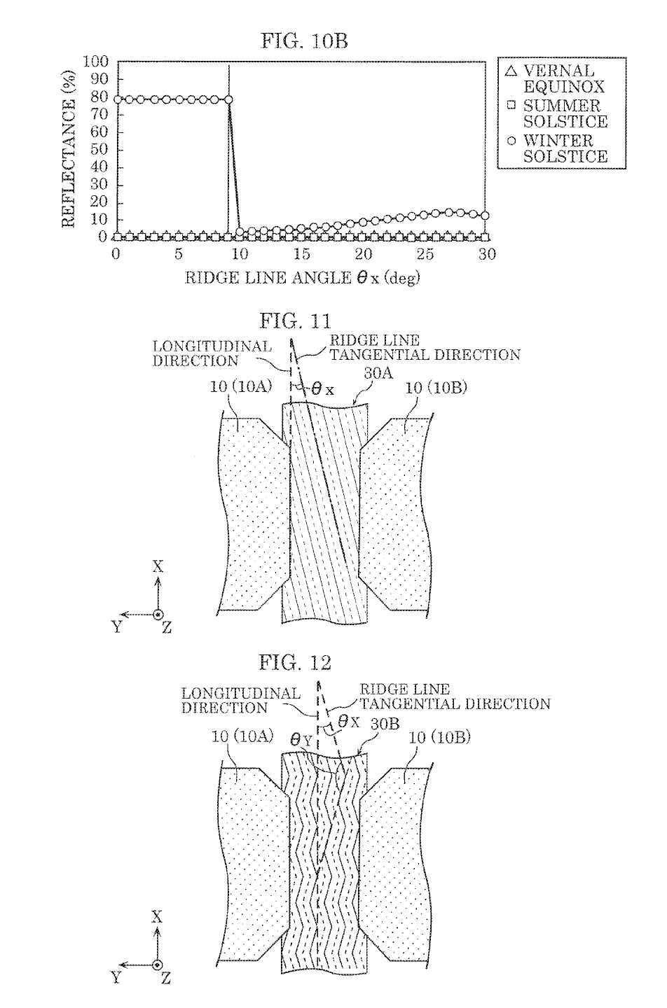

FIG. 10A is a graph illustrating a relationship between a ridge angle of a light reflector and a probability of incident light reaching a solar cell. FIG. 10B is a graph illustrating a relationship between a ridge angle of a light reflector and reflectance (of incident light reflected to the outside of a solar cell module).

It is clear from the graphs of FIG. 10A and FIG. 10B that at the culmination times of the vernal equinox and the summer solstice, no light is reflected to the outside of the solar cell module and all incident light reaches the solar cell even when ridge line angle θ_{X} is varied.

At the culmination time of the winter solstice, ridge line angle θ_{X} of 9 degrees is a singular point, and approximately 80% of incident light is emitted to the outside of the solar cell module when ridge angle θ_{X} is less than 9 degrees. In contrast, it is clear that when ridge line angle θ_{X} is greater than 9 degrees, a percentage of incident light emitted to the outside of the solar cell module is significantly reduced (to approximately 20% or less) and almost all incident light reaches the cell surface.

As described above, it is possible to inhibit incident light from being emitted to the outside of the solar cell module, by setting ridge line angle θ_{X} of light reflector 30 to greater than 9 degrees particularly at a culmination time at which sunlight has the highest incident intensity. Accordingly, it is possible to successfully retain the appearance of the solar cell module during a time period in which the illumination on the module surface is greatest when the incident light is emitted to the outside of the solar cell module.

A range (the lower limit and upper limit) of the maximum angle θ_{X} (deg) formed by the longitudinal direction and the ridge line direction of the protruding portion in light reflector 30 according to Embodiment 1 is expressed by Expression 4 below.

$$\begin{matrix}[ Math . 4 ] & \\ 9 ( deg ) < {θ}_{X} < {cos}^{- 1} ( \frac{W}{L} ) & ( Expression 4 )\end{matrix}$$

It should be noted that an optimum angle that can inhibit the incident light from being emitted to the outside of the solar cell module varies within the range of maximum angle θ_{X} (deg) expressed by above Expression 4, depending on an installation location of the solar cell module, an installation angle of the solar cell module, a season, a time period, etc. In contrast, in solar cell module 1 according to Embodiment 1, the shape of the ridge line of light reflector 30 is the wavy shape, and thus the tangential direction of the ridge line has a predetermined range in which maximum angle θ_{X} (deg) is greatest. Accordingly, for example, it is possible to produce the advantageous effect of reducing the illumination on the part of the module surface not only at a specific time such as the culmination time of the winter solstice shown in FIG. 10A and FIG. 10B but also in a long time period.

Returning to FIG. 1 and FIG. 2, the following describes the protective components, the encapsulant, and the frame.

### [1-6. Front Surface Protective Component, Back Surface Protective Component]

Front surface protective component 40 is a component that protects the front surface of solar cell module 1, and protects the inside (e.g., solar cells 10) of solar cell module 1 from the outside environment such as rainstorm and an external shock. As shown in FIG. 2, front surface protective component 40 is disposed on the side facing the front surface of solar cell 10, and protects the light-receiving surface on the side facing the front surface of solar cell 10.

Front surface protective component 40 includes a light-transmissive component that transmits light in a wavelength band used for photoelectric conversion in solar cell 10. Front surface protective component 40 is, for example, a glass substrate (a transparent glass substrate) made of a transparent glass material or a resin substrate made of a hard resin material being film-shaped or plate-shaped and having light-transmissive properties and waterproof properties.

Back surface protective component 50 is a component that protects the back surface of solar cell module 1, and protects the inside of solar cell module 1 from the outside environment. As shown in FIG. 2, back surface protective component 50 is disposed on the side facing the back surface of solar cell 10, and protects the light-receiving surface on the side facing the back surface of solar cell 10.

Back surface protective component 50 is, for example, a film- or plate-shaped resin sheet made of a resin material such as polyethylene terephthalate (PET) or polyethylene naphthalate (PEN).

When solar cell module 1 is a monofacial module, back surface protective component 50 may be a non-light-transmissive plate or film. It should be noted that back surface protective component 50 is not limited to a non-light-transmissive component, and may be a light-transmissive component such as a glass sheet or a glass substrate made of a glass material.

### [1-7. Encapsulant]

Encapsulant 60 is disposed between front surface protective component 40 and back surface protective component 50. Front surface protective component 40 and back surface protective component 50 are bonded and fixed to solar cell 10 by encapsulant 60. In Embodiment 1, encapsulant 60 fills up the space between front surface protective component 40 and back surface protective component 50.

As shown in FIG. 4A, encapsulant 60 includes front surface encapsulant 61 and back surface encapsulant 62. Each of front surface encapsulant 61 and back surface encapsulant 62 covers solar cells 10 arranged in a matrix.

Solar cells 10 are entirely covered with encapsulant 60 by being subjected to lamination processing (laminated) in a state in which, for example, solar cells 10 are interposed between front surface encapsulant 61 and back surface encapsulant 62 that are sheet-shaped.

Specifically, solar cells 10 are connected by first interconnectors 20 to form strings 10S and light reflectors 30 are disposed, after which strings 10S are interposed between front surface encapsulant 61 and back surface encapsulant 62. Further, front surface protective component 40 and back surface protective component 50 are disposed on front surface encapsulant 61 and back surface encapsulant 62, respectively. Subsequently, the resultant structure is subjected to, for example, theme compression bonding in a vacuum at a temperature of at least 100° C. Front surface encapsulant 61 and back surface encapsulant 62 are heated and melted by the thermo compression bonding, which results in encapsulant 60 that seals solar cells 10.

Front surface encapsulant 61 before lamination processing is, for example, a resin sheet made of a resin material such as EVA or polyolefin, and is disposed between solar cells 10 and front surface protective component 40. Front surface encapsulant 61 is caused to fill up the space mainly between solar cells 10 and front surface protective component 40 by lamination processing.

Front surface encapsulant 61 is made of a light-transmissive material. In Embodiment 1, a transparent resin sheet made of EVA is used as front surface encapsulant 61 before lamination processing.

Back surface encapsulant 62 before lamination processing is, for example, a resin sheet made of a resin material such as EVA or polyolefin, and is disposed between solar cells 10 and back surface protective component 50. Back surface encapsulant 62 is caused to fill up the space mainly between solar cells 10 and back surface protective component 50 by lamination processing.

When solar cell module 1 in Embodiment 1 is a monofacial module, back surface encapsulant 62 is not limited to a light-transmissive material, and may be made of a colored material such as a black material or a white material.

### [1-8. Frame]

Frame 70 is an outer frame that covers a perimeter portion of solar cell module 1. Frame 70 is, for example, an aluminum frame. As shown in FIG. 1, each of four frames 70 is fitted to a corresponding one of the four sides of solar cell module 1. For example, each frame 70 is bonded to a corresponding one of the sides of solar cell module 1 with an adhesive.

It should be noted that although not shown, solar cell module 1 includes a terminal box for drawing power generated by solar cells 10. The terminal box is fixed to, for example, back surface protective component 50. The terminal box includes circuit components mounted on a circuit board.

### Embodiment 2

A solar cell module according to Embodiment 2 differs from the solar cell module according to Embodiment 1 only in an uneven structure of a light reflective film included in a light reflector. Hereinafter, description of configurations that are the same as those of the solar cell module according to Embodiment 1 will be omitted, and description will be focused on different configurations.

### [2-1. Surface Structure of Light Reflector]

FIG. 11 is a transparent plan view (an enlarged transparent plan view around light reflector 30A) of the solar cell module according to Embodiment 2. Specifically, FIG. 11 is a plan view obtained by seeing through light reflector 30A and two solar cells 10 adjacent to light reflector 30A from a side facing front surface protective component 40 (the Z axis positive side). It should be noted that a cross section structure of light reflector 30A is the same as the cross section structure of li at reflector 30 shown in FIG. 4A. Further, in FIG. 11, an insulating component and an adhesive component of light reflector 30A are illustrated as being transparent to clearly show an uneven structure of a light reflective film included in light reflector 30A. As shown in FIG. 11, the light reflective film has a protruding portion (peak) and a recessed portion (trough) that are repeated in a latitudinal direction (the Y axis direction) of light reflector 30A. Further, when solar cell 10 is seen in a plan view, the ridge line of the protruding portion (peak) has a linear shape, and a tangential direction of the ridge line of the protruding portion (peak) and a longitudinal direction of light reflector 30A intersect. In other words, angle θ_{X} (deg) formed. by the tangential direction of the ridge line of the protruding portion (peak) and the longitudinal direction of reflector 30A is a predetermined angle other than 0 degrees.

It should be noted that a range of angle θ_{X} (deg) of light reflector 30A is expressed by Expression 4 described in Embodiment 1.

With the solar cell module according to Embodiment 2, the characteristic surface structure of light reflector 30A shown in FIG. 11 makes it possible to reduce illumination on part of the module surface.

It should be noted that the ridge line shape of light reflector 30A is the linear shape in Embodiment 2, and thus the tangential direction of the ridge line has certain angle θ_{X} (deg) relative to the longitudinal direction of light reflector 30A. Accordingly, for example, Embodiment 2 is suitable to produce the effect of reducing illumination on part of the module surface at a specific time in which there is the highest demand for addressing such a problem, such as the culmination time of the winter solstice shown in FIG. 10A and FIG. 10B.

### Embodiment 3

A solar cell module according to Embodiment 3 differs from the solar cell module according to Embodiment 1 only in an uneven structure of a light reflective film included in a light reflector. Hereinafter, description of configurations that are the same as those of the solar cell module according to Embodiment 1 will be omitted, and description will he focused on different configurations.

### [3-1. Surface Structure of Light Reflector]

FIG. 12 is a transparent plan view (an enlarged transparent plan view around light reflector 30B) of the solar cell module according to Embodiment 3. Specifically, FIG. 12 is a plan view obtained by seeing through light reflector 30B and two solar cells 10 adjacent to light reflector 30B from a side facing front surface protective component 40 (the Z axis positive side). It should be noted that a cross section structure of light reflector 30B is the same as the cross section structure of light reflector 30 shown in FIG. 4A. Further, in FIG. 12, an insulating component and an adhesive component of light reflector 30B are illustrated as being transparent to clearly show an uneven structure of a light reflective film included in light reflector 30B. As shown in FIG. 12, the light reflective film has a protruding portion (peak) and a recessed portion (trough) that are repeated in a latitudinal direction (the Y axis direction) of light reflector 30B. Further, when solar cell 10 is seen in a plan view, the ridge line of the protruding portion (peak) has a zigzag shape in which a point of discontinuity appears cyclically, and a tangential direction of part of the ridge line of the protruding portion (peak) and a longitudinal direction of light reflector 30B intersect. In other words, angle θ_{X} (deg) formed by the tangential direction of the ridge line of the protruding portion (peak) and the longitudinal direction of light reflector 30B is a predetermined angle other than 0 degrees.

It should be noted that a range of angle θ_{X} (deg) of light reflector 30B is expressed by Expression 4 described in Embodiment 1.

Moreover, as shown in FIG. 12, it is desirable that angle θ_{Y} formed by two adjacent straight lines constituting the ride line of the protruding portion having the zigzag shape be at least 150 degrees and at most 160 degrees.

With the solar cell module according to Embodiment 3, the characteristic surface structure of light reflector 30B shown in FIG. 12 makes it possible to reduce illumination on part of the module surface.

It should be noted that in Embodiment 3, there are two types of angle θ_{X} (deg) formed by the tangential direction of the ridge line and the longitudinal. direction of light reflector 30B because the ridge line shape of light reflector 30B is the zigzag shape formed by the two types of straight line. Accordingly, for example, it is possible to produce the effect of reducing the illumination on the part of the module surface not at a time of one type such as the culmination time of the winter solstice shown in FIG. 10A. and FIG. 10B but in time periods of types such as a predetermined time period in the morning and a predetermined time period in the afternoon.

### (Advantageous Effects Etc.)

Solar cell module 1 according to one aspect of the embodiments includes: solar cell 10; light reflector 30 above a surface of solar cell 10 or around solar cell 10, light reflector 30 being elongated and including light reflective film 31 and insulating component 32; front surface protective component 40 that covers the surface of solar cell 10; and front surface encapsulant 61 between (i) solar cell 10 and light reflector 30 and (ii) front surface protective component 40. Light reflective film 31 has uneven structure 30a in which recessed portion 30v and protruding portion 30v are repeated in a direction crossing a longitudinal direction of light reflector 30, and a tangential direction of at least part of a ridge line of protruding portion 30t and the longitudinal direction intersect when solar cell 10 is seen in a plan view.

In conventional solar cell module 500, the ridge line of the protruding portion in the uneven structure of light reflector 530 disposed in the gap region between adjacent solar cells 10A and 10B is parallel to the longitudinal direction. In this case, most of the reflected light from light reflector 530 may be emitted outside of solar cell module 500 depending on the incident angle of the incident light. Accordingly, the emitted reflected light illuminates the module surface more strongly, which impairs the appearance of solar cell module 500 and further causes visual discomfort to a person.

In contrast, solar cell module 1 according to Embodiment 1 can inhibit the reflected light from light reflector 30 from being emitted to the outside of solar cell module 1 because the tangential direction of the at least part of the ridge line of protruding portion 30t and the longitudinal direction intersect. Accordingly, since the illumination on the part, of the module surface can be reduced, it is possible to successfully retain the appearance of the module surface.

Moreover, maximum angle θ_{X} (deg) is expressed by above Expression 3 and Expression 4, where θ_{X} denotes the maximum angle formed by the ridge line direction of protruding portion 30t and the above longitudinal direction, θ_{X} (deg) denotes a vertex angle of protruding portion 30t, and d denotes a distance from an interface of front surface protective component 40 and an external space of solar cell module 1 to first point P1 on light reflective film 31.

With this, it is possible to inhibit incident light from being emitted to the outside of the solar cell module, by setting ridge line angle θ_{X} of light reflector 30 to greater than 9 degrees particularly at a culmination time at which sunlight has the highest incident intensity. Accordingly, it is possible to successfully retain the appearance of the solar cell module during a time period in which the illumination on the module surface is greatest when the incident light is emitted to the outside of the solar cell module.

Moreover, a vertex angle θ_{Z} of protruding portion 30t may be at least 115 degrees and at most 125 degrees.

With this, it is possible to efficiently redistribute the light incident on the gap region between solar cells 10, onto solar cells 10. As a result, it is possible to increase the photoelectric conversion efficiency of solar cell module 1 as a whole.

Moreover, the ridge line of protruding portion 30t in the uneven structure may be wavy when solar cell 10 is seen in the plan view.

An optimum angle that can inhibit the incident light from being emitted to the outside of the solar cell module varies within the range of maximum angle θ_{X} (deg) expressed by above Expression 4, depending on an installation location of the solar cell module, an installation angle of the solar cell module, a season, a time period, etc. In view of this, in solar cell module 1, the shape of the ridge line of light reflector 30 is the wavy shape, and thus the tangential direction of the ridge line has a predetermined range in which maximum angle θ_{X} (deg) is greatest. Accordingly, for example, it is possible to produce the advantageous effect of reducing the illumination on the part of the module surface not only at a specific time such as the culmination time of the winter solstice but also in a long time period.

Moreover, the ridge line of protruding portion 30t in the uneven structure may be linear when solar cell 10 is seen in the plan view.

With this, the tangential direction of the ridge line has certain angle θ_{X} (deg) relative to the longitudinal direction of light reflector 30A. Accordingly, for example, such a configuration is suitable to produce the effect of reducing illumination on part of the module surface at a specific time in which there is the highest demand for addressing such a problem, such as the culmination time of the winter solstice.

Moreover, the ridge line of protruding portion 30t in the uneven structure may be zigzag when solar cell 10 is seen in the plan view.

With this, there are two types of angle θ_{X} (deg) formed by the tangential direction of the ridge line and the longitudinal direction of light reflector 30B. Accordingly, for example, it is possible to produce the effect of reducing the illumination on the part of the module surface not at a time of one type such as the culmination time of the winter solstice but in time periods of types such as a predetermined time period in the morning and a predetermined time period in the afternoon.

Moreover, an angle θ_{Y} formed by two adjacent straight lines constituting the ridge line of the protruding portion that is zigzag may be at least 150 degrees and at most 160 degrees.

With this, it is possible to inhibit the reflected light from light reflector 30B from being emitted to the outside of the solar cell module. Accordingly, since the illumination on the part of the module surface can be reduced, it is possible to successfully retain the appearance of the module surface.

Moreover, solar cell module 1 may include solar cells 10 that are coplanar and spaced apart from each other, and on a side facing surfaces of solar cells 10, light reflector 30 may extend across two of solar cells 10 that are adjacent.

With this, since the effective region of solar cell 10 is not shaded by light reflector 30 in an overlapping portion of solar cell 10 with light reflector 30, it is possible to reduce blocked light.

### Other Variations Etc.

Although the solar cell module according to the present disclosure has been described above based on Embodiments 1 to 3, the present disclosure is not limited to Embodiments 1 to 3.

For example, as with light reflector 30B according to Embodiment 3, an angle formed by two tangential lines of a wavy ridge line may be at least 150 degrees and at most 160 degrees in light reflector 30 according to Embodiment 1. With this, it is possible to inhibit reflected light from light reflector 30 from being emitted to the outside of the solar cell module.

Moreover, although light reflectors 30, 30A, and 30B are each disposed for a corresponding space between adjacent solar cells 10 in a space between two adjacent strings 10S in respective Embodiments 1 to 3, the present disclosure is not limited to this. For example, light reflectors 30, 30A, and 30B may be each disposed extending across the corresponding space between solar cells 10 along the longitudinal direction of two adjacent strings 10S, in the space between two adjacent strings 10S. As an example, light reflectors 30, 30A, and 30B may each be a single elongated light reflective sheet that entirely covers string 10S.

Moreover, although light reflectors 30, 30A, and 30B are disposed in all the spaces between strings 10S in respective Embodiments 1 to 3, light reflectors 30, 30A, and 30B may be disposed only in some of the spaces. In other words, there may be spaces between the solar cells in which light reflectors 30, 30A, and 30B are not disposed.

Moreover, although light reflective film 31 is disposed on the entire surface of insulating component 32 or 36 in each of Embodiments 1 to 3, the present disclosure is not limited to this. For example, light reflective film 31 between two adjacent solar cells 10 may be severed. With this, every when light reflective film 31 that is conductive touches solar cell 10, it is possible to inhibit generation of leakage current between adjacent solar cells 10 via light reflective film 31

Furthermore, not only light reflective film 31 but also the insulating component and the adhesive component may be severed. In addition, instead of a single light reflector being disposed extending across a space between two solar cells 10, light reflectors may be disposed side by side between two solar cells 10.

Moreover, the adhesive component may contain voids in each of Embodiments 1 to 3. The voids are, for example, air bubbles in an air layer.

When the light reflector is bonded to solar cell 10 by thermo compression bonding, the light reflector may warp due to heat contraction of the insulating component that is a PET layer. As a result, solar cell 10 may break, and desired reflective characteristics of the light reflector may be not achieved. In other words, stress caused by the heat contraction of the insulating component may be directly transferred to solar cell 10, and solar cell 10 may crack.

In view of this, the adhesive component that serves as an adhesive layer for the light reflector and solar cell 10 may contain voids. This decreases the stress caused by the heat contraction of the insulating component. In other words, the stress caused by the heat contraction of the insulating component is applied to fill the voids, and thus it is possible to decrease the stress transferred to solar cell 10. In consequence, the warping of the light reflector can be inhibited. Accordingly, solar cell 10 can be inhibited from cracking, and thus productivity and reliability of a solar cell module improve.

Moreover, although the semiconductor substrate of solar cell 10 is an n-type semiconductor substrate in each of Embodiments 1 to 3, the semiconductor substrate may be a p-type semiconductor substrate.

Moreover, in each of Embodiments 1 to 3, the solar cell module may be a monofacial module in which only front surface protective component 40 serves as a light-receiving surface, or may be a bifacial module in which both front surface protective component 40 and back surface protective component 50 serve as light-receiving surfaces.

Moreover, although a semiconductor material of a photoelectric converter of solar cell 10 is silicon in each of Embodiments 1 to 3, the present disclosure is not limited to this. Examples of the semiconductor material of the photoelectric converter of solar cell 10 may include gallium arsenide (GaAs) or indium phosphide (InP).

Although only sonic exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

What is claimed is:

1. A solar cell module, comprising:
a solar cell;
a light reflector above a surface of the solar cell or around the solar cell, the light reflector being elongated and including a light reflective film and an insulating component;
a protective component that covers the surface of the solar cell; and
an encapsulant between (i) the solar cell and the light reflector and (ii) the protective component,
wherein the light reflective film has an uneven structure in which a recessed portion and a protruding portion are repeated in a direction crossing a longitudinal direction of the light reflector, and
a tangential direction of at least part of a ridge line of the protruding portion and the longitudinal direction intersect when the solar cell is seen in a plan view.

2. The solar cell module according to claim 1,
where W denotes a width of a region of the light reflector that is seen from a side on which an incident light is incident; L denotes a horizontal range front a first point when, in the case where the incident light is incident on the first point on the light reflective film, the incident light is reflected by the protective component and reaches a horizontal plane including he surface of the solar cell; θ_{X} (deg) denotes a maximum angle formed by the tangential direction and the longitudinal direction when the solar cell is seen in the plan view; θ_{Z} (deg) denotes a vertex angle of the protruding portion; and d denotes a distance from an interface between the protective component and an external space of the solar cell module to the first point.
wherein a maximum angle θ_{X} (deg) satisfies the following relationships:
$$\begin{matrix}[ Math . 1 ] & \\ 9 ( deg ) < {θ}_{X} < {cos}^{- 1} ( \frac{W}{L} ) & ( Expression 1 ) \\ [ Math . 2 ] & \\ L = - 2 d \cdot tan {θ}_{Z} & ( Expression 2 )\end{matrix}$$

3. The solar cell module according to claim 2,
wherein the vertex angle θ_{Z} of the protruding portion is at least 115 degrees and at most 125 degrees.

4. The solar cell module according to claim 1,
wherein the ridge line of the protruding portion in the uneven structure is wavy when the solar cell is seen in the plan view.

5. The solar cell module according to claim 1,
wherein the ridge line of the protruding portion in the uneven structure is linear when the solar cell is seen in the plan view.

6. The solar cell module according to claim 1,
wherein the ridge line of the protruding portion in the uneven structure is zigzag when the solar cell is seen in the plan view.

7. The solar cell module according to claim 6,
wherein an angle θ_{Y} formed by two adjacent straight lines constituting the ridge line of the protruding portion that is zigzag is at least 150 degrees and at most 160 degrees.

8. The solar cell module according to claim 1, comprising:
a plurality of solar cells each being the solar cell, the plurality of solar cells being coplanar and spaced apart from each other,
wherein on a side facing back surfaces of the plurality of solar cells, the light reflector extends across two of the plurality of solar cells that are adjacent.
